(19) United States
(12) Patent Application Publication
(10) Pub. No.: US 2025/0126900 A1
(43) Pub. Date: Apr. 17, 2025

(54) OPTICAL DEVICE AND PRODUCTION METHOD THEREFOR

(71) Applicant: TOYODA GOSEI CO., LTD., Kiyosu-shi (JP)

(72) Inventors: Koji OKUNO, Kiyosu-shi (JP); Koichi GOSHONOO, Kiyosu-shi (JP); Masaki OYA, Kiyosu-shi (JP)

(21) Appl. No.: 18/912,112

(22) Filed: Oct. 10, 2024

(30) Foreign Application Priority Data
Oct. 17, 2023 (JP) 2023-178867

(51) Int. Cl. H01L 31/0693; H01L 31/0304; H01L 31/18; H01L 33/00; H01L 33/14; H01L 33/32

(52) U.S. Cl. CPC H10F 10/144; H10F 71/1278; H10F 71/128; H10F 77/1243; H10F 77/1246; H10H 20/01; H10H 20/0137; H10H 20/8162; H10H 20/8252

(57) ABSTRACT

A method for producing an optical device includes: forming an n-type layer over a substrate by a MOCVD method; forming a first active layer over the n-type layer by a MOCVD method; forming an intermediate layer over the first active layer by a MOCVD method; forming a second active layer having a band gap energy different from the band gap energy of the first active layer over the intermediate layer by a MOCVD method; forming a first p-type layer over the second active layer by a MOCVD method; forming a groove having a depth reaching the intermediate layer from a side of the first p-type layer; forming an electron blocking layer by sputtering over the intermediate layer exposed at a bottom surface of the groove; forming a semiconductor layer over the electron blocking layer by sputtering; and forming a second p-type layer as defined herein.

### CROSS-REFERENCE TO RELATED APPLICATION

This application is based on and claims priority under 35 USC 119 from Japanese Patent Application No. 2023-178867 filed on Oct. 17, 2023.

### TECHNICAL FIELD

The present invention relates to an optical device and a production method therefor.

### p BACKGROUND ART

In recent years, high definition of displays has been required, and a micro LED display, in which each pixel is a minute LED on the order of 1 μm to 100 μm, has attracted attention. Various full-color methods are known, and for example, a method in which three active layers emitting blue, green, and red light are sequentially stacked on the same substrate is known.

Patent Literature 1: JP5854419B

### SUMMARY OF INVENTION

In the method in which three active layers emitting blue, green, and red light are sequentially stacked on the same substrate, a step of once completing crystal growth, taking a wafer out of a growth furnace, forming grooves, and then charging the wafer back into the growth furnace to regrow a p-type layer is necessary.

However, according to studies of the inventors, it has been found that the wafer is contaminated with impurities during this step, and the impurities act as donors, forming an unintended n-type layer at a regrowth interface. Then, the active layer is sandwiched between n-type layers, resulting in a decrease in light emission efficiency.

The present invention has been made in view of such a background, and an object thereof is to provide an optical device having a reduced decrease in light emission efficiency, and a production method therefor.

An aspect of the present invention is directed to a method for producing an optical device, the method comprising:
an n-type layer formation step of forming an n-type layer made of an n-type Group III nitride semiconductor over a substrate by a MOCVD method;
a first active layer formation step of forming a first active layer having a predetermined band gap energy over the n-type layer by a MOCVD method;
an intermediate layer formation step of forming an intermediate layer made of an In-containing Group III nitride semiconductor over the first active layer by a MOCVD method;
a second active layer formation step of forming a second active layer having a band gap energy different from the band gap energy of the first active layer over the intermediate layer by a MOCVD method;
a first p-type layer formation step of forming a first p-type layer made of a p-type Group III nitride semiconductor over the second active layer by a MOCVD method;
a groove formation step of forming a groove having a depth reaching the intermediate layer from the first p-type layer;
an electron blocking layer formation step of forming an electron blocking layer made of a Group III nitride semiconductor by sputtering over the intermediate layer exposed at a bottom surface of the groove;
a semiconductor layer formation step of forming a semiconductor layer made of a Group III nitride semiconductor over the electron blocking layer by sputtering; and
a second p-type layer formation step of forming a second p-type layer by ion-implanting a p-type impurity into the semiconductor layer and performing a heat treatment to convert the semiconductor layer into a p-type layer.

Another aspect of the present invention is directed to an optical device comprising:
an n-type layer made of an n-type Group III nitride semiconductor provided over a substrate;
a first active layer having a predetermined band gap energy provided over the n-type layer;
an intermediate layer made of an In-containing Group III nitride semiconductor provided over the first active layer;
a second active layer having a band gap energy different from the band gap energy of the first active layer provided over the intermediate layer;
a first p-type layer made of a p-type Group III nitride semiconductor provided over the second active layer;
a groove having a depth reaching the intermediate layer from the first p-type layer;
an electron blocking layer made of a Group III nitride semiconductor provided over the intermediate layer exposed at a bottom surface of the groove; and
a second p-type layer made of a p-type Group III nitride semiconductor provided over the electron blocking layer, wherein
a concentration of O and Si at an interface between the intermediate layer and the electron blocking layer is 1×10¹⁶ cm⁻³ or less.

According to the above aspects, since the electron blocking layer and the second p-type layer are formed by sputtering, an amount of impurity at the interface between the intermediate layer and the electron blocking layer can be sufficiently reduced. Therefore, a decrease in light emission efficiency can be prevented.

### BRIEF DESCRIPTION OF DRAWINGS

FIG. 1 is a cross-sectional view showing a configuration of a light emitting element according to an embodiment, which shows a cross section in a direction perpendicular to a main surface of a substrate.

FIG. 2 is a diagram showing a step of producing the light emitting element according to the embodiment.

FIG. 3 is a diagram showing a step of producing the light emitting element according to the embodiment.

FIG. 4 is a diagram showing a step of producing the light emitting element according to the embodiment.

FIG. 5 is a diagram showing a step of producing the light emitting element according to the embodiment.

FIG. 6 is a cross-sectional view showing a configuration of a light emitting element according to a modification 1 of the embodiment, which shows a cross section in a direction perpendicular to a main surface of a substrate.

FIG. 7 is a cross-sectional view showing a configuration of a light emitting element according to a modification 2 of the embodiment, which shows a cross section in a direction perpendicular to a main surface of a substrate.

### DESCRIPTION OF EMBODIMENTS

A method for producing an optical device includes: an n-type layer formation step of forming an n-type layer made of an n-type Group III nitride semiconductor on a substrate by a MOCVD method; a first active layer formation step of forming a first active layer having a predetermined band gap energy on the n-type layer by a MOCVD method; an intermediate layer formation step of forming an intermediate layer made of an In-containing Group III nitride semiconductor on the first active layer by a MOCVD method; a second active layer formation step of forming a second active layer having a band gap energy different from the band gap energy of the first active layer on the intermediate layer by a MOCVD method; a first p-type layer formation step of forming a first p-type layer made of a p-type Group III nitride semiconductor on the second active layer by a MOCVD method; a groove formation step of forming a groove having a depth reaching the intermediate layer from the first p-type layer; an electron blocking layer formation step of forming an electron blocking layer made of a Group III nitride semiconductor by sputtering on the intermediate layer exposed at a bottom surface of the groove; a semiconductor layer formation step of forming a semiconductor layer made of a Group III nitride semiconductor on the electron blocking layer by sputtering; and a second p-type layer formation step of forming a second p-type layer by ion-implanting a p-type impurity into the semiconductor layer and performing a heat treatment to convert the semiconductor layer into a p-type layer.

In the above method for producing an optical device, in the semiconductor layer formation step, the semiconductor layer may also be formed on the first p-type layer.

In the above method for producing an optical device, after the semiconductor layer formation step, a high resistance region may be formed by implanting ions into a region of the semiconductor layer in contact with the second active layer and the intermediate layer. Current leakage can be prevented.

In the above method for producing an optical device, the electron blocking layer formation step may include a step of irradiating a wafer with a plasma gas to remove an impurity from a surface of the wafer before forming the electron blocking layer.

In the above method for producing an optical device, the second p-type layer formation step may include a step of ion-implanting a p-type impurity into the electron blocking layer and performing a heat treatment to convert the electron blocking layer to a p-type layer. When the electron blocking layer is converted into a p-type layer, holes can be efficiently implanted into the first active layer. In addition, a larger barrier can be provided to electrons, and an electron blocking function can be improved.

In the above method for producing an optical device, the optical device may be a light emitting element, a light receiving element, or a solar cell.

An optical device includes: an n-type layer made of an n-type Group III nitride semiconductor provided on a substrate; a first active layer having a predetermined band gap energy provided on the n-type layer; an intermediate layer made of an In-containing Group III nitride semiconductor provided on the first active layer; a second active layer having a band gap energy different from the band gap energy of the first active layer provided on the intermediate layer; a first p-type layer made of a p-type Group III nitride semiconductor provided on the second active layer; a groove having a depth reaching the intermediate layer from the first p-type layer; an electron blocking layer made of a Group III nitride semiconductor provided on the intermediate layer exposed at a bottom surface of the groove; and a second p-type layer made of a p-type Group III nitride semiconductor provided on the electron blocking layer, in which a concentration of O and Si at an interface between the intermediate layer and the electron blocking layer is 1×10¹⁶ cm⁻³ or less.

### (Embodiment)

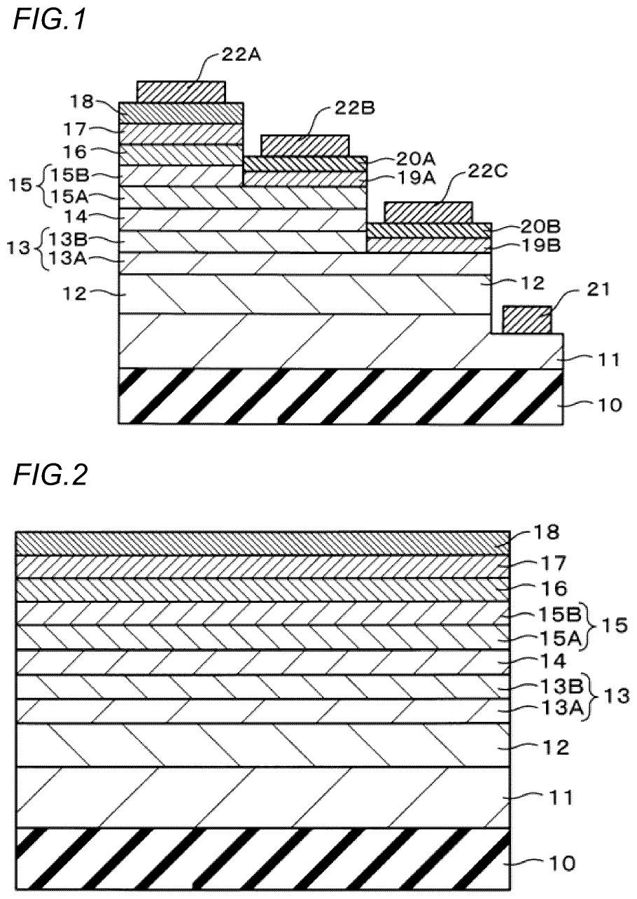

FIG. 1 is a diagram showing a configuration of a light emitting element according to an embodiment. The light emitting element according to the embodiment can emit blue, green, and red light. In addition, the light emitting element according to the embodiment is a flip-chip type that extracts light from a back surface of a substrate, and is mounted on a mounting substrate (not shown) in a face-down manner. Note that, in the embodiment, one pixel has a structure of one chip, but a monolithic type may be used. That is, it may be a micro LED display element in which element structures in the embodiment are arranged in a matrix on the same substrate.

### 1. Configuration of Light Emitting Element

As shown in FIG. 1, the light emitting element according to the embodiment includes a substrate 10, an n-type layer 11, a first active layer 12, a first intermediate layer 13, a second active layer 14, a second intermediate layer 15, a third active layer 16, electron blocking layers 17, 19A, and 19B, p-type layers 18, 20A, and 20B, an n-side electrode 21, and p-side electrodes 22A to 22C.

The substrate 10 is a growth substrate on which a Group III nitride semiconductor is grown. For example, sapphire, Si, GaN, or ScAlMgO₄ (SAM).

The n-type layer 11 is an n-type semiconductor layer provided on the substrate 10 via a low-temperature buffer layer or a high-temperature buffer layer (not shown). However, the buffer layer may be provided as necessary, and may not be provided when the substrate is GaN. The n-type layer 11 is, for example, n-GaN, n-AlGaN, or n-InGaN. A concentration of Si is, for example, 1×10¹⁸ cm⁻³ to 100×10¹⁸ cm⁻³.

The first active layer 12 is a light emitting layer having an SQW or MQW structure provided on the n-type layer 11. An emission wavelength is blue and is 430 nm to 480 nm. The first active layer 12 has a structure in which a barrier layer made of AlGaN and a well layer made of InGaN are alternately stacked for 1 to 9 pairs. The number of pairs is more preferably 1 to 7, and still more preferably 1 to 5.

A base layer may be provided between the n-type layer 11 and the first active layer 12 as necessary. The base layer is a semiconductor layer having a superlattice structure provided on the n-type layer 11, and is a layer for relaxing lattice strain in a semiconductor layer formed on the base layer. The base layer is formed by alternately stacking Group III nitride semiconductor thin films having different compositions (for example, two of GaN, InGaN, and AlGaN), and the number of pairs is, for example, 3 to 30. The base layer may be non-doped or doped with Si by about 1×10¹⁷ cm⁻³ to 100×10¹⁷ cm⁻³. It is not necessary to have a superlattice structure as long as the strain can be relaxed.

In addition, an ESD layer may be provided between the n-type layer 11 and the base layer. The ESD layer is a layer provided to increase an electrostatic breakdown voltage. The ESD layer is, for example, non-doped or lightly Si-doped GaN, InGaN, or AlGaN.

The first intermediate layer 13 is a semiconductor layer provided on the first active layer 12. The first intermediate layer 13 is a layer provided to enable light emission from the first active layer 12 and light emission from the second active layer 14 to be separately controlled. In addition, it also has the role of protecting the first active layer 12 from etching damage when forming a second groove 31 to be described later.

The first intermediate layer 13 has a structure in which a non-doped intermediate layer 13A and an n-type intermediate layer 13B are sequentially stacked from the first active layer 12. The non-doped intermediate layer 13A and the n-type intermediate layer 13B may be made of the same material except for impurities. A reason why the first intermediate layer 13 has such a two-layer structure will be described later.

The material of the first intermediate layer 13 is an In-containing Group III nitride semiconductor, and is preferably InGaN, for example. With a surfactant effect of In, roughness on a surface of the first intermediate layer 13 can be prevented and surface flatness can be improved. In addition, the lattice strain can be relaxed.

It is sufficient that an In composition (a molar ratio of In to all Group III metals in the Group III nitride semiconductor) of the first intermediate layer 13 is set to have a band gap in which light emitted from the first active layer 12 and light emitted from the second active layer 14 are not absorbed. A preferred In composition is 10% or less, more preferably 5% or less, and still more preferably 2% or less. When the In composition is greater than 10%, the surface of the first intermediate layer 13 is rough. The In composition is any as long as it is greater than 0%, and may be at a doping level (a level that does not form a mixed crystal). For example, GaN having a concentration of In of 1×10¹⁴ cm⁻³ or more and 1×10²² cm⁻³ or less.

The non-doped intermediate layer 13A is non-doped, and the n-type intermediate layer 13B is Si-doped. A concentration of Si in the n-type intermediate layer 13B is preferably 1×10¹⁷ cm⁻³ to 1000×10¹⁷ cm⁻³. It is preferably 10×10¹⁷ cm⁻³ to 100×10¹⁷ cm⁻³, and more preferably 20×10¹⁷ cm⁻³ to 80×10¹⁷ cm⁻³. The n-type intermediate layer 13B may be modulated and doped with Si, or there may be a non-doped region in a partial region of the n-type intermediate layer 13B.

A thickness of the first intermediate layer 13 is preferably 20 nm to 150 nm. When the thickness is more than 150 nm, the surface of the first intermediate layer 13 may be rough. When the thickness is less than 20 nm, there is a possibility that it is difficult to control a depth of the second groove 31 to be within the non-doped intermediate layer 13A when forming the second groove 31 to be described later. The thickness is more preferably 30 nm to 100 nm, and still more preferably 50 nm to 80 nm.

In addition, a thickness of the non-doped intermediate layer 13A is preferably 10 nm or more. This is for controlling an etching depth and avoiding etching damage to the first active layer 12. In addition, a thickness of the n-type intermediate layer 13B is preferably 10 nm or more. This is for independently controlling light emitting characteristics of each active layer.

The second active layer 14 is a layer provided on the first intermediate layer 13, and has a quantum well structure of SQW or MQW. An emission wavelength is green and is 510 nm to 570 nm. The quantum well structure has a structure in which a barrier layer made of GaN or AlGaN and a well layer made of InGaN are alternately stacked for 1 to 7 pairs.

A strain relaxation layer may be provided between the first intermediate layer 13 and the second active layer 14. When the strain relaxation layer is provided, the strain in the second active layer 14 stacked thereon can be relaxed, and the crystal quality can be improved. The strain relaxation layer has an SQW structure or an MQW structure in which a barrier layer and a well layer are sequentially stacked, and has a quantum well structure in which a thickness of the well layer is adjusted to be small so as not to emit light. For example, when the thickness of the well layer is set to 1 nm or less, it is possible to prevent the well layer from emitting light. The barrier layer is AlGaN, and the well layer is InGaN. It is sufficient that a wavelength corresponding to a band edge energy in the well layer of the strain relaxation layer is shorter than the emission wavelength of the second active layer 14, and is, for example, 400 nm to 460 nm when the emission wavelength is 500 nm to 560 nm.

The second intermediate layer 15 is a semiconductor layer provided on the second active layer 14. The second intermediate layer 15 is provided for a reason same as that of the first intermediate layer 13, and is a layer provided to enable light emission from the second active layer 14 and light emission from the third active layer 16 to be separately controlled. In addition, it also has the role of protecting the second active layer 14 from etching damage when forming a first groove 30 to be described later.

The second intermediate layer 15 has a structure in which a non-doped intermediate layer 15A and an n-type intermediate layer 15B are sequentially stacked from the second active layer 14. The non-doped intermediate layer 15A and the n-type intermediate layer 15B have a structure same as that of the non-doped intermediate layer 13A and the n-type intermediate layer 13B. That is, the non-doped intermediate layer 15A and the n-type intermediate layer 15B are made of a material same as that of the non-doped intermediate layer 13A and the n-type intermediate layer 13B except for impurities, and a thickness range is also the same as that of the non-doped intermediate layer 13A and the n-type intermediate layer 13B. The non-doped intermediate layer 15A is non-doped, and the n-type intermediate layer 15B is Si-doped.

The third active layer 16 is a layer provided on the second intermediate layer 15, and has a quantum well structure of SQW or MQW. An emission wavelength is red and is 590 nm to 700 nm. The quantum well structure has a structure in which a barrier layer made of InGaN and a well layer made of InGaN are alternately stacked for 1 to 7 pairs. The number of pairs is more preferably 1 to 5, and still more preferably 1 to 3.

A strain relaxation layer may be provided between the second intermediate layer 15 and the third active layer 16. When the strain relaxation layer is provided, the strain in the third active layer 16 stacked thereon can be relaxed, and the crystal quality can be improved. The strain relaxation layer has, for example, a structure in which a first strain relaxation layer and second strain relaxation layer are sequentially stacked from the second intermediate layer 15.

The first strain relaxation layer and the second strain relaxation layer have a structure same as the strain relaxation layer between the first intermediate layer 13 and the second active layer 14 described above. A wavelength corresponding to a band edge energy in a well layer of the first strain relaxation layer is, for example, 400 nm to 460 nm. A wavelength corresponding to a band edge energy in a well layer of the second strain relaxation layer is, for example, 510 nm to 570 nm.

The electron blocking layer 17 is a semiconductor layer provided on the third active layer 16. The electron blocking layer 17 is a layer for blocking electrons implanted from the n-type layer 11 in order to efficiently confine the electrons in the third active layer 16. In addition, the electron blocking layer 17 is layer not only having an electron blocking function but also functioning as a protective layer for protecting the third active layer 16. The electron blocking layer 17 may be made of a material having a band gap wider than that of the well layer of the third active layer 16, such as AlGaN, GaN, or InGaN. A thickness of the electron blocking layer 17 is preferably 2.5 nm to 50 nm, and more preferably 5 nm to 25 nm. The electron blocking layer 17 may be doped with impurities or Mg. In this case, a concentration of Mg is preferably 1×10¹⁸ cm⁻³ to 1000×10¹⁸ cm⁻³.

The p-type layer 18 is a semiconductor layer provided on the electron blocking layer 17, and includes a first layer and a second layer sequentially from the electron blocking layer 17. The first layer is preferably p-GaN or p-InGaN. A thickness of the first layer is preferably 10 nm to 500 nm, more preferably 10 nm to 200 nm, and still more preferably 10 nm to 100 nm. A concentration of Mg in the first layer is preferably 1×10¹⁹ cm⁻³ to 100×10¹⁹ cm⁻³. The second layer is preferably p-GaN or p-InGaN. A thickness of the second layer is preferably 2 nm to 50 nm, more preferably 4 nm to 20 nm, and still more preferably 6 nm to 10 nm. A concentration of Mg in the second layer is preferably 1×10²⁰ cm⁻³ to 100×10²⁰ cm⁻³.

A partial region on a surface of the p-type layer 18 is etched to provide grooves, and from the p-type layer 18, the first groove 30 reaching the second intermediate layer 15, the second groove 31 reaching the first intermediate layer 13, and a third groove 32 reaching the n-type layer 11 are provided.

The first groove 30 has a depth reaching the non-doped intermediate layer 15A of the second intermediate layer 15. In this way, by removing the n-type intermediate layer 15B of the second intermediate layer 15 below the p-side electrode 22B, the n-type intermediate layer 15B is not positioned on the second active layer 14, and the second active layer 14 emits light. The second groove 31 has a depth reaching the non-doped intermediate layer 13A of the first intermediate layer 13. For the same reason, by removing the n-type intermediate layer 13B of the first intermediate layer 13 below the p-side electrode 22C, the n-type intermediate layer 13B is not positioned on the first active layer 12, and the first active layer 12 emits light.

The electron blocking layers 19A and 19B are semiconductor layers respectively provided on the non-doped intermediate layer 15A exposed on a bottom surface of the first groove 30 and on the non-doped intermediate layer 13A exposed on a bottom surface of the second groove 31, and are layers for blocking electrons implanted from the n-type layer 11 in order to efficiently confine the electrons in the first active layer 12 and the second active layer 14.

The electron blocking layers 19A and 19B are layers formed by sputtering as to be described later. Therefore, no impurities such as O and Si are present and no n-type layer is present at an interface between the non-doped intermediate layer 15A and the electron blocking layer 19A and an interface between the non-doped intermediate layer 13A and the electron blocking layer 19B. Here, “no impurities such as O and Si are present” means that a concentration of the impurity is sufficiently small, for example, 1×10¹⁶ cm⁻³ or less. The concentration is more preferably 1×10¹⁵ cm⁻³ or less.

The electron blocking layers 19A and 19B may be a single layer of GaN or AlGaN, or may have a structure in which two or more of AlGaN, GaN, and InGaN are stacked, or a structure in which the above materials are stacked with only the composition ratio changed. Alternatively, the electron blocking layers 19A and 19B may have a superlattice structure. Having a superlattice structure, the electrons can be more efficiently blocked. The superlattice structure is, for example, a structure in which p-AlGaN and p-InGaN are alternately stacked, or a structure in which p-AlGaN and p-GaN are alternately stacked. However, in consideration of the ease of formation by sputtering, the electron blocking layers 19A and 19B are preferably a single layer or a layer in which an Al composition monotonically decreases or increases.

A thickness of the electron blocking layers 19A and 19B is preferably 5 nm to 50 nm, and more preferably 5 nm to 25 nm.

In addition, the electron blocking layers 19A and 19B are of a Mg-doped p-type. Mg is introduced by ion implantation to be described later. When the electron blocking layers 19A and 19B are of a p-type, holes can be efficiently implanted into the active layer. In addition, a larger barrier can be provided to electrons, and an electron blocking function can be improved. The electron blocking layers 19A and 19B may be non-doped, for the reasons described above, and are preferably doped with Mg to be of a p-type. A concentration of Mg in the electron blocking layers 19A and 19B is preferably 1×10¹⁹ cm⁻³ to 100×10¹⁹ cm⁻³.

The p-type layers 20A and 20B are semiconductor layers respectively provided on the electron blocking layers 19A and 19B, and each include a first layer and a second layer sequentially from the electron blocking layers 19A and 19B. The p-type layers 20A and 20B are layers formed by sputtering to be described later, and are introduced with Mg by ion implantation.

The first layer is preferably p-GaN or p-InGaN. A thickness of the first layer is preferably 10 nm to 500 nm, more preferably 10 nm to 200 nm, and still more preferably 10 nm to 100 nm. A concentration of Mg in the first layer is preferably 1×10¹⁹ cm⁻³ to 100×10¹⁹ cm⁻³. The second layer is preferably p-GaN or p-InGaN. A thickness of the second layer is preferably 2 nm to 50 nm, more preferably 4 nm to 20 nm, and still more preferably 6 nm to 10 nm. A concentration of Mg in the second layer is preferably 1×10²⁰ cm⁻³ to 100×10²⁰ cm⁻³.

Note that, in the embodiment, the p-type layers 20A and 20B have a two-layer structure, but in consideration of the ease of formation by sputtering, the p-type layers 20A and 20B are preferably a single layer, and preferably a Mg-doped single GaN layer.

Note that, in the embodiment, the electron blocking layer 19A and the electron blocking layer 19B, and the p-type layer 20A and the p-type layer 20B are formed separately, but they may be formed as a continuous film. In this case, a layer made of a material same as that of the electron blocking layers 19A and 19B is also formed on a side surface of the second groove 31.

The n-side electrode 21 is an electrode provided on the n-type layer 11 exposed on the bottom surface of the third groove 32. When the substrate 10 is made of a conductive material, the n-side electrode 21 may be provided on a back surface of the substrate 10 without providing the third groove 32. A material of the n-side electrode 21 is, for example, Ti/Al or V/Al.

The p-side electrodes 22A to 22C are electrodes respectively provided on the p-type layers 18, 20A, and 20B. A material of the p-side electrodes 22A to 22C is preferably a material that has a high reflectance of light at the emission wavelength and that has low contact resistance with respect to the p-type layers 18, 20A, and 20B. For example, Ag, Ni/Au, Co/Au, ITO/Ni/Al, Rh, or Ru. Among the red light emitted from the third active layer 16, light directed toward the p-type layer 18 is reflected by the p-side electrode 22A and goes toward the substrate 10. Similarly, among the green light emitted from the second active layer 14, light directed toward the p-type layer 20A is reflected by the p-side electrode 22B and goes toward the substrate 10, and among the blue light emitted from the first active layer 12, light directed toward the p-type layer 20B is reflected by the p-side electrode 22C and goes toward the substrate 10.

As described above, in the light emitting element according to the embodiment, since the electron blocking layers 19A and 19B and the p-type layers 20A and 20B are layers formed by sputtering, no n-type layer made of impurities such as O and Si is present between the non-doped intermediate layer 15A and the electron blocking layer 19A, and between the non-doped intermediate layer 13A and the electron blocking layer 19B. Therefore, with the light emitting element according to the embodiment, a decrease in light emission efficiency can be prevented.

### 2. Operation of Light Emitting Element

Next, an operation of the light emitting element according to the embodiment will be described. In the light emitting element according to the embodiment, red light can be emitted from the third active layer 16 by applying a voltage between the p-side electrode 22A and the n-side electrode 21, green light can be emitted from the second active layer 14 by applying a voltage between the p-side electrode 22B and the n-side electrode 21, and blue light can be emitted from the first active layer 12 by applying a voltage between the p-side electrode 22C and the n-side electrode 21. The above light emission can be controlled independently, and two or more of blue, green, and red light can be emitted at the same time.

In this way, in the light emitting element according to the embodiment, blue, green, and red light emission can be controlled by selecting the electrode to which a voltage is applied, and it can be used as one pixel of a display.

### 3. Steps of Producing Light Emitting Element

Next, steps of producing the light emitting element according to the embodiment will be described with reference to the drawings.

First, the substrate 10 is prepared, and the substrate is subjected to a heat treatment by adding hydrogen, nitrogen, and, if necessary, ammonia.

Next, a buffer layer is formed on the substrate 10, and the n-type layer 11, the first active layer 12, the first intermediate layer 13, the second active layer 14, the second intermediate layer 15, the third active layer 16, the electron blocking layer 17, and the p-type layer 18 are sequentially formed on the buffer layer (see FIG. 2). Each layer is formed by using a MOCVD method. A preferred growth temperature for each layer is as follows.

The growth temperature for the first active layer 12 is preferably 700° C. to 950° C. The crystal quality can be improved and the light emission efficiency can be enhanced. The first active layer 12 includes a well layer and a barrier layer, and the well layer and the barrier layer may be formed at the same temperature or may be formed at different temperatures within the above temperature range. When the temperatures are different, it is preferable that the growth temperature for the well layer is lower than the growth temperature for the barrier layer.

The growth temperature for the first intermediate layer 13 is preferably 700° C. to 1000° C. This is for preventing thermal damage to the first active layer 12. When the temperature is lower than 700° C., pits and point defects due to threading dislocations are likely to occur. The growth temperature is more preferably 800° C. to 950° C., and still more preferably 850° C. to 950° C.

The growth temperature for the second active layer 14 is preferably 650° C. to 950° C. The crystal quality can be improved and the light emission efficiency can be enhanced. The second active layer 14 includes a well layer and a barrier layer, and the well layer and the barrier layer may be formed at the same temperature or may be formed at different temperatures within the above temperature range. When the temperatures are different, it is preferable that the growth temperature for the well layer is lower than the growth temperature for the barrier layer. In addition, the growth temperature for the second active layer 14 is preferably lower than the growth temperature for the first active layer 12.

The growth temperature for the second intermediate layer 15 is preferably in a range same as that of the growth temperature for the first intermediate layer 13. However, the growth temperature for the second intermediate layer 15 is preferably lower than the growth temperature for the first intermediate layer 13. This is because the second active layer 14 that emits green light is more susceptible to thermal damage than the first active layer 12 that emits blue light, and an influence of the strain at an interface is larger.

The growth temperature for the third active layer 16 is preferably 500° C. to 950° C. The crystal quality can be improved and the light emission efficiency can be enhanced. The third active layer 16 includes a well layer and a barrier layer, and the well layer and the barrier layer may be formed at the same temperature or may be formed at different temperatures within the above temperature range. When the temperatures are different, it is preferable that the growth temperature for the well layer is lower than the growth temperature for the barrier layer. In addition, the growth temperature for the third active layer 16 is preferably lower than the growth temperature for the second active layer 14.

The growth temperature for the electron blocking layer 17 and the p-type layer 18 is preferably 500° C. to 950° C. This is for preventing thermal damage to the first active layer 12, the second active layer 14, and the third active layer 16. In order to improve crystallinity of the electron blocking layer 17 and the p-type layer 18, the growth temperature is preferably high, more preferably 600° C. to 900° C., and still more preferably 700° C. to 900° C.

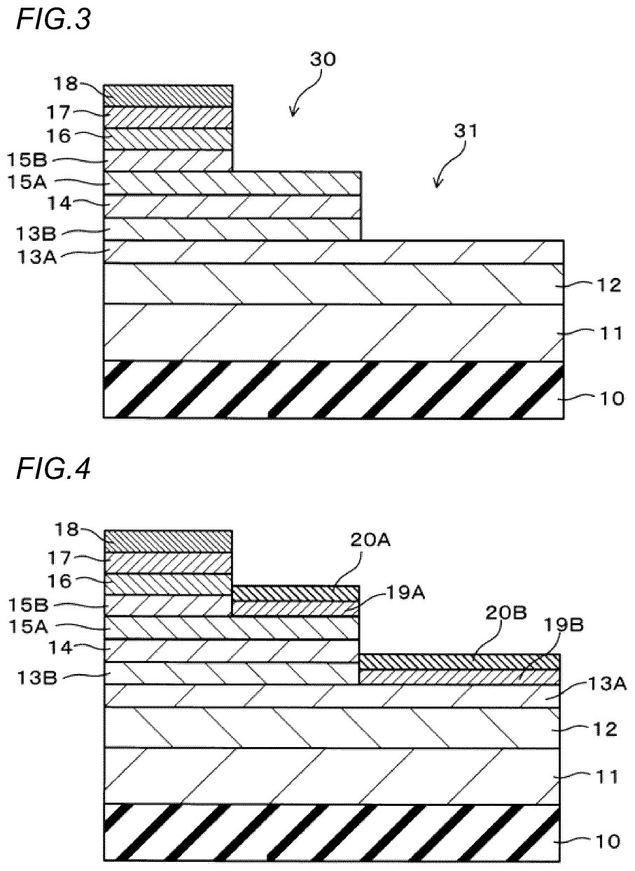

Next, a partial region on the surface of the p-type layer 18 is dry-etched until it reaches the non-doped intermediate layer 15A of the second intermediate layer 15 to form the first groove 30, and is dry-etched until it reaches the non-doped intermediate layer 13A of the first intermediate layer 13 to form the second groove 31 (see FIG. 3).

In the process of forming the first groove 30 and the second groove 31, the wafer is once taken out of the growth furnace and subjected to an etching step. Therefore, the wafer is exposed to the atmosphere, and a surface of the wafer is contaminated with impurities such as O and Si.

Next, on the non-doped intermediate layer 15A of the second intermediate layer 15 exposed by the first groove 30 and on the non-doped intermediate layer 13A of the first intermediate layer 13 exposed by the second groove 31, the electron blocking layers 19A and 19B made of non-doped AlGaN are formed by sputtering, and on the electron blocking layers 19A and 19B, the p-type layers 20A and 20B made of non-doped GaN or InGaN are also formed by sputtering (see FIG. 4). Note that, the p-type layers 20A and 20B are not of p-type at this stage, but are referred to as p-type since they will be of p-type later.

As a sputtering target, an AlGaN sintered body is used for forming the electron blocking layers 19A and 19B, and a GaN or InGaN sintered body is used for forming the p-type layers 20A and 20B. In addition, a method of growing GaN using a Ga target with nitrogen plasma may also be used. During the sputtering, the temperature is 20° C. to 700° C., and the pressure is 0.1 Pa to 1 Pa. The gas used is Ar or nitrogen. The sputtering method may be an RF method, a DC method, or the like.

In the sputtering, the wafer is irradiated with a plasma gas such as Ar or nitrogen as a pretreatment. With the plasma gas, impurities such as O and Si on the surface of the wafer can be removed. Therefore, no n-type layer made of impurities such as O and Si is present at the interface between the non-doped intermediate layer 15A and the electron blocking layer 19A and the interface between the non-doped intermediate layer 13A and the electron blocking layer 19B. Therefore, a decrease in light emission efficiency can be prevented.

In addition, when the wafer is irradiated with the plasma gas, the etching damage during the formation of the first groove 30 and the second groove 31 can be removed, and the characteristics of the element can be improved. In addition, particles adhering to the wafer can be removed, and the defect rate can be reduced.

In addition, since the electron blocking layers 19A and 19B and the p-type layers 20A and 20B can be formed at a low temperature by sputtering, thermal damage to the first active layer 12, the second active layer 14, and the third active layer 16 can be prevented.

In the sputtering, since hydrogen or ammonia is not used as in the case of the MOCVD method, there is also no possibility that hydrogen from these gases inactivate Mg in the electron blocking layer 17 or the p-type layer 18, causing Mg to be highly resistive.

Next, Mg ions are implanted into the p-type layers 20A and 20B and the electron blocking layers 19A and 19B from a surface side of the p-type layers 20A and 20B. An implantation energy is controlled such that an implantation peak is in the p-type layers 20A and 20B. The ion implantation may be performed at room temperature, and is preferably performed at a temperature higher than room temperature. An amount of implantation damage can be reduced. For example, the ion implantation is performed at a temperature of 400° C. or higher. In order to prevent the thermal damage, it is preferable to perform the ion implantation at 600° C. or lower.

In this way, the p-type layers 20A and 20B and the electron blocking layers 19A and 19B are doped with Mg by the ion implantation. This is because it is difficult to directly form a Mg-doped Group III nitride semiconductor by sputtering.

Note that, in the embodiment, Mg ions are implanted into both the p-type layers 20A and 20B and the electron blocking layers 19A and 19B, but Mg ions may be implanted into only the p-type layers 20A and 20B. However, since the electron blocking layers 19A and 19B are preferably of p-type, it is preferable to implant ions into the electron blocking layers 19A and 19B as in the embodiment. Alternatively, the electron blocking layers 19A and 19B may be converted into a p-type layer by implanting Mg ions only into the p-type layers 20A and 20B and diffusing Mg from the p-type layers 20A and 20B into the electron blocking layers 19A and 19B in a subsequent heat treatment step.

Next, a heat treatment is performed to activate the implanted Mg ions. Preferred heat treatment conditions are as follows. The heat treatment temperature is 800° C. to 1200° C., the pressure is 100 kPa to 1 GPa, and the atmosphere is an inert gas such as nitrogen or Ar, or ammonia. The heat treatment time is 1 second to 10 minutes. With the heat treatment, Mg is activated, and the p-type layers 20A and 20B and the electron blocking layers 19A and 19B can be converted into a p-type layer. In addition, the p-type layer 18 can be converted into a p-type layer. It is particularly preferable to perform the heat treatment in a nitrogen atmosphere or an ammonia atmosphere. This is to prevent the escape of nitrogen from the semiconductor layer. In order to reduce thermal damage to the active layer, it is preferable to perform the heat treatment at a temperature as low as possible. At a higher temperature, a shorter time is preferred.

A photoresist, SiO₂, or the like can be used as a mask for the sputtering and the ion implantation. The mask used during the sputtering may be left as it is and used as a mask for the ion implantation.

The ion implantation may be performed a number of times by changing an acceleration voltage. A distribution of Mg in a thickness direction can be adjusted.

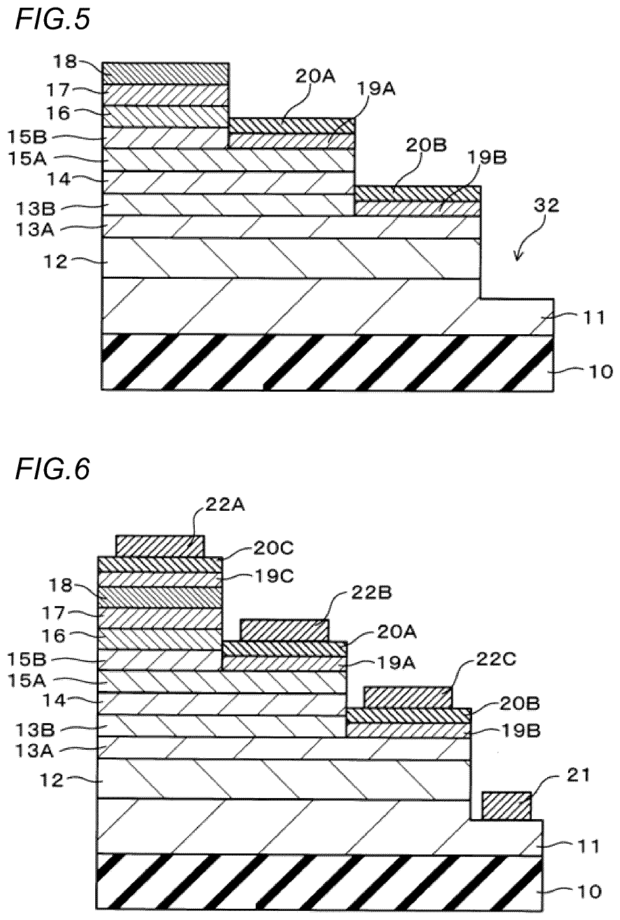

Next, a partial region on a surface of the p-type layer 20B is dry-etched until it reaches the n-type layer 11 to form the third groove 32 (see FIG. 5). Then, the n-side electrode 21 is formed on the n-type layer 11 exposed at the bottom surface of the third groove 32, and the p-side electrode 22A to 22C are formed on the p-type layers 18, 20A, and 20B. With the above, the light emitting element according to the embodiment is produced.

As described above, in the method for producing a light emitting element according to the embodiment, since the p-type layers 20A and 20B and the electron blocking layers 19A and 19B are formed by sputtering and ion implantation, no n-type layer made of impurities such as O and Si is present between the non-doped intermediate layer 15A and the electron blocking layer 19A, and between the non-doped intermediate layer 13A and the electron blocking layer 19B. Therefore, a decrease in light emission efficiency can be prevented.

### (Modification 1 of Embodiment)

As shown in FIG. 6, at the same time with the formation of the electron blocking layers 19A and 19B and the p-type layers 20A and 20B, an electron blocking layer 19C and a p-type layer 20C may be sequentially formed on the p-type layer 18 by sputtering from the p-type layer 18. According to the modification 1, the thickness on each active layer can be controlled and it is easy to control an optical interference effect. In addition, since no mask is used, the product steps can be simplified. Further, since the p-type layer 20C has a surface on which no mask is formed, the contact with the p-side electrode 22A can be improved.

### (Modification 2 of Embodiment)

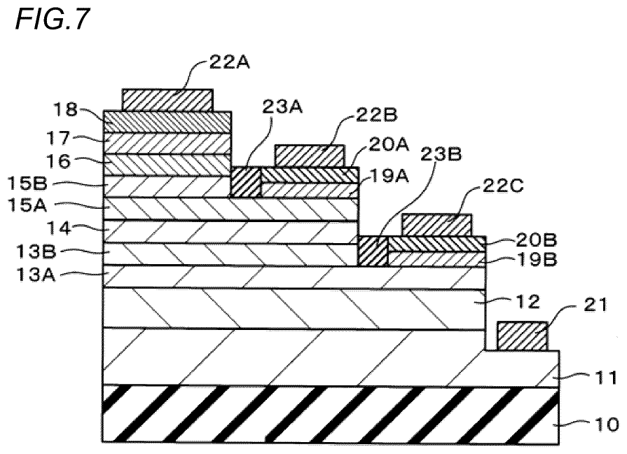

As shown in FIG. 7, high resistance regions 23A and 23B may be formed by ion implantation in a region of the electron blocking layer 19A and the p-type layer 20A in contact with the n-type intermediate layer 15B and the third active layer 16, and in a region of the electron blocking layer 19B and the p-type layer 20B in contact with the n-type intermediate layer 13B and the second active layer 14. Accordingly, current leakage can be prevented between the p-side electrode 22A and the p-side electrode 22B and between the p-side electrode 22B and the p-side electrode 22C, and the light emitted from the first active layer 12, the second active layer 14, and the third active layer 16 can be more easily controlled. The type of the element for ion implantation may be any type that can increase the resistance. For example, B, Zn, or Mg can be used. The resistance may be increased by co-doping with a donor such as Si or Ge and an acceptor such as Mg.

### Other Modifications

In the embodiment, the light is emitted in three colors, red, green, and blue, but the present invention is not limited to this, and it is sufficient that the light is emitted in two or more colors with different emission wavelengths. For example, the light may also be emitted in four colors, red, yellow, green, and blue.

The embodiment shows a case where the optical device according to the present invention is used as a light emitting element, but the present invention can also be used as a light receiving element. In the case of being used as a light receiving element, for example, red, green, and blue light can be received separately.

The light emitting element and the light receiving element in the present invention can be used as a light source for generating an optical signal in a wavelength division multiplexing optical communication device, and as a light receiving element for receiving an optical signal, and the optical communication device can be simplified and the cost can be reduced. For example, the red light, the green light, and the blue light emitted by the light emitting element according to the embodiment can be wavelength-multiplexed to generate and transmit a transmission signal. In addition, when a reception signal is received by the light receiving element according to the embodiment, the red light, the green light, and the blue light can be separately received.

When a large number of light receiving elements according to the embodiment are arranged, the light receiving elements can also be used as a solar cell.

### REFERENCE SIGNS LIST

10: substrate
11: n-type layer
12: first active layer
13: first intermediate layer
14: second active layer
15: second intermediate layer
16: third active layer
17, 19A, 19B: electron blocking layer
18, 20A, 20B: p-type layer
21: n-side electrode
22A to 22C: p-side electrode

What is claimed is:

1. A method for producing an optical device, the method comprising:
forming an n-type layer comprising an n-type Group III nitride semiconductor over a substrate by a MOCVD method;
forming a first active layer having a band gap energy over the n-type layer by a MOCVD method;
forming an intermediate layer comprising a Group III nitride semiconductor containing In over the first active layer by a MOCVD method;
forming a second active layer having a band gap energy different from the band gap energy of the first active layer over the intermediate layer by a MOCVD method;
forming a first p-type layer comprising a p-type Group III nitride semiconductor over the second active layer by a MOCVD method;
forming a groove having a depth reaching the intermediate layer from a side of the first p-type layer;
forming an electron blocking layer comprising a Group III nitride semiconductor by sputtering over the intermediate layer exposed at a bottom surface of the groove;
forming a semiconductor layer comprising a Group III nitride semiconductor over the electron blocking layer by sputtering; and
forming a second p-type layer by ion-implanting a p-type impurity into the semiconductor layer and performing a heat treatment to convert the semiconductor layer to p-type.

2. The method for producing an optical device according to claim 1, wherein the forming of the semiconductor layer comprises: forming the semiconductor layer over the first p-type layer.

3. The method for producing an optical device according to claim 1, wherein after the forming of the semiconductor layer, a high resistance region is formed by implanting ions into a region of the semiconductor layer in contact with the second active layer and the intermediate layer.

4. The method for producing an optical device according to claim 1, wherein the forming of the electron blocking layer comprises: irradiating a wafer with a plasma gas to remove an impurity from a surface of the wafer before forming the electron blocking layer.

5. The method for producing an optical device according to claim 1, wherein the forming of the second p-type layer comprises: ion-implanting a p-type impurity into the electron blocking layer and performing a heat treatment to convert the electron blocking layer to p-type.

6. The method for producing an optical device according to claim 1, wherein the optical device is a light emitting element.

7. The method for producing an optical device according to claim 1, wherein the optical device is a light receiving element.

8. The method for producing an optical device according to claim 1, wherein the optical device is a solar cell.

9. An optical device comprising:
an n-type layer comprising an n-type Group III nitride semiconductor provided over a substrate;
a first active layer having a band gap energy provided over the n-type layer;
an intermediate layer comprising a Group III nitride semiconductor containing In provided over the first active layer;
a second active layer having a band gap energy different from the band gap energy of the first active layer provided over the intermediate layer;
a first p-type layer comprising a p-type Group III nitride semiconductor provided over the second active layer;
a groove having a depth reaching the intermediate layer from a side of the first p-type layer;
an electron blocking layer comprising a Group III nitride semiconductor provided over the intermediate layer exposed at a bottom surface of the groove; and
a second p-type layer comprising a p-type Group III nitride semiconductor provided over the electron blocking layer, wherein
a total concentration of O and Si at an interface between the intermediate layer and the electron blocking layer is 1×10¹⁶ cm⁻³ or less.
